(19) United States
(12) Patent Application Publication
(10) Pub. No.: US 2006/0108628 A1
(43) Pub. Date: May 25, 2006

(54) MULTI-LEVEL SPLIT-GATE FLASH MEMORY

(76) Inventors: CHIH-WEI HUNG, HSIN-CHU CITY (TW); HUI-HUNG KUO, KAOHSIUNG COUNTY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,746

(22) Filed: Nov. 25, 2004

(51) Int. Cl. H01L 29/788

(52) U.S. Cl. 257/315

(57) ABSTRACT

A multi-level split-gate flash memory is provided. The flash memory includes a substrate, a memory row, a dummy select gate, a source region and a drain region. The memory cell row includes a plurality of serially connected memory cells with each memory cell having a stacked gate structure and a select gate at least. The stacked gate structure of each memory cell is disposed on the substrate. The select gate is disposed on a sidewall of the stacked gate structure. The dummy select gate is disposed on one side of the memory cell row adjacent to the sidewall of the stacked gate structure at the end of the memory cell row. The source region and the drain region are disposed in the substrate beside the dummy select gate and the memory cell row.

### BACKGROUND OF THE INVENTION

1. Field of the Invention

The present invention relates to a memory device. More particularly, the present invention relates to a multi-level split-gate flash memory.

2. Description of the Related Art

Flash memory is a type of non-volatile memory that permits multiple data writing, reading and erasing operation. Moreover, the stored data will be retained even after power to the device is removed. Hence, the flash memory has become one of the most widely adopted non-volatile memories for personal computer and electronic equipment.

A typical flash memory has a floating gate and a control gate fabricated using doped polysilicon. To prevent data read-out errors resulting from the over-erasure of the flash memory during an erasing operation, an additional select gate is normally set up on the sidewall of the control gate and the floating gate above the substrate to form a split-gate structure.

At present, the most common types of flash memory array includes the NOR gate array and the NAND gate array. Since the memory cells in a NAND gate array are serially connected together, its level of integration is higher than a NOR gate array. However, because of the serial connection in a NAND gate array, more complicated steps are required to program data into the memory cells of the NAND gate array and reading or erasing data from the memory cells of the NAND gate array. To program the memory cells of a NAND gate array, the Fowler-Nordheim tunneling effect is utilized so that electrons can penetrate through the tunneling oxide layer into the floating gate. Yet, due to the higher programming speed of the memory cell closest to the common source compared with other memory cells in the same memory cell row, memory cell failure may occur. Hence, the memory is unsuitable for multi-level operation. For example, in a memory cell row with 15 memory cells, programming the memory cell closest to the common source region to 5V requires only 10 microseconds, but programming the other memory 14 memory cells to 3V requires 200 microseconds.

To resolve the aforementioned problem, the most common method is to increase the width of the memory cell closest to the common source region. For example, the width of the stacked gate structure closest to the common source region is increased from 0.15 μm to 0.30 μm. However, operating problems are often encountered due to the difference in width between the memory cell closest to the common source region and the other memory cells in the same memory cell row so that the cells can hardly be used as a multi-level memory. Consequently, how to produce a flash memory having multi-level memory operating capacity is an important research topic for the manufacturing industry.

### SUMMARY OF THE INVENTION

Accordingly, at least one objective of the present invention is to provide a multi-level split-gate flash memory structure capable of resolving the problem of not being able to operate a conventional flash memory as a multi-level memory device.

At least a second objective of the present invention is to provide an alternative multi-level split-gate flash memory structure capable of resolving the problem of not being able to operate a conventional flash memory as a multi-level memory device.

To achieve these and other advantages and in accordance with the purpose of the invention, as embodied and broadly described herein, the invention provides a multi-level split-gate flash memory.

The flash memory includes a substrate, a memory cell row, a dummy select gate, a source region and a drain region. The memory cell row includes a plurality of serially connected memory cells with each memory cell having a stacked gate structure, a select gate, a second inter-gate dielectric layer and a select gate dielectric layer. The stacked gate structure of each memory cell is disposed on the substrate. The stacked gate structure includes a tunneling dielectric layer, a floating gate, a first inter-gate dielectric layer and a control gate stacked sequentially over the substrate. The select gate is disposed on one of the sidewalls of the stacked gate structures. The second inter-gate dielectric layer is disposed between the sidewall of the stacked gate structure and the select gate. The select gate dielectric layer is disposed between the select gate and the substrate. The dummy select gate is disposed on one side of the memory cell row adjacent to the sidewall of the stacked gate structure at the very end of the memory cell row. The source region and the drain region are disposed in the substrate beside the dummy select gate and the memory cell row.

In the present invention, a dummy select gate is set up within the flash memory. Therefore, in a programming operation, the period for programming the memory cell closest to the dummy select gate is increased so that the programming speed is almost identical to the programming speed of the other memory cells in the memory cell row. In other words, the flash memory of the present may operate as a multi-level memory.

The present invention also provides an alternative multi-level split-gate flash memory. The flash memory includes a substrate, a memory cell row, a dummy cell, a source region and a drain region. The memory cell row includes a plurality of memory cells serially connected together with each memory cell having a stacked gate structure, a select gate, a second inter-gate dielectric layer and a select gate dielectric layer. The dummy memory cell includes a dummy stacked gate structure and a dummy select gate. The memory cell row and the stacked gate structures of various memory cells are disposed on the substrate. Each stacked gate structure includes a tunneling dielectric layer, a floating gate, a first inter-gate dielectric layer and a control gate stacked sequentially over the substrate. The select gate is disposed on one of the sidewalls of the stacked gate structures. The second inter-gate dielectric layer is disposed between the sidewall of the stacked gate structure and the select gate. The select gate dielectric layer is disposed between the select gate and the substrate. The dummy memory cell is disposed on one side of the memory cell row. The dummy stacked gate structure of the dummy memory cell is disposed on the substrate. Furthermore, the dummy stacked gate structure includes at least a dummy control gate. The dummy select gate is disposed on one of the sidewalls of the dummy stacked gate structure adjacent to the sidewall of the stacked gate structure of the memory cell located at the very end of the memory cell row. The source region and the drain region are disposed in the substrate beside the dummy memory cell and the memory cell row.

In the present invention, a dummy memory cell is set up within the flash memory. Therefore, in a programming operation, the period for programming the memory cell closest to the dummy memory cell is increased so that the programming speed is almost identical to the programming speed of the other memory cells in the memory cell row. In other words, the flash memory of the present may operate as a multi-level memory.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a multi-level split-gate flash memory according to one preferred embodiment of the present invention.

FIG. 2 is a schematic cross-sectional view of a multi-level split-gate flash memory according to another preferred embodiment of the present invention.

FIGS. 3A through 3D are schematic cross-sectional view showing the steps for fabricating a multi-level split-gate flash memory according to one preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

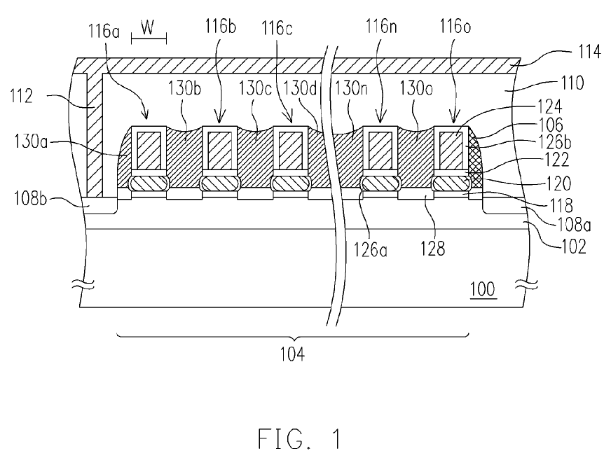

FIG. 1 is a schematic cross-sectional view of a multi-level split-gate flash memory according to one preferred embodiment of the present invention. In the present embodiment, a 15-cell NAND gate memory cell row is used as an example in the following illustration. As shown in FIG. 1, the multi-level split-gate flash memory of the present invention includes at least a substrate 100, a P-type well 102, a memory cell row 104, a dummy select gate 106, a source region 108a, a drain region 108b, an inter-layer dielectric layer 110, a plug 112 and a conductive layer 114. The memory cell row 104 includes a plurality of serially connected memory cells 116a˜116o, a plurality of inter-gate dielectric layers 126a and 126b, a select gate dielectric layer 128 and a plurality of select gates 130˜130o. Furthermore, each memory cell includes a stacked gate structure having a tunneling dielectric layer 118, a floating gate 120, an inter-gate dielectric layer 122 and a control gate 124. The substrate 100 is P-type silicon substrate and a P-type well 102 is disposed in the substrate 100, for example.

The stacked gate structures 116a˜116o of the memory cell row 104 are disposed on the substrate 100 with each stacked gate structure comprising a tunneling dielectric layer 118, a floating gate 120, an inter-gate dielectric layer 122 and a control gate 124 sequentially stacked over the substrate 100. Furthermore, the width W of the control gates 120 in the stacked gate structures 116a˜116o are identical. In one preferred embodiment, the width W is about 0.15 μm, for example.

The select gates 130a˜130o are disposed on the sidewalls of the stacked gate structures 116a˜116o. Furthermore, the select gates 130b˜130o are adjacent to another stacked gate structures 116a˜116n. In other words, the select gate (for example: the select gate 130b) completely fills the gap between a pair of stacked gate structures (for example: the stacked gate structures 116a and 116b).

The inter-gate dielectric layer 126a is disposed between the sidewall of the floating gates 120 and the select gates 130a˜130o.

The inter-gate dielectric layer 126b is disposed on the top portion of the control gates 124 and between the sidewall of the control gates 124 and the select gates 130a˜130o.

The select gate dielectric layer 128 is disposed between the select gates 130a˜130o and the substrate 100.

The dummy select gate 106 is disposed on one side of the memory cell row 104 adjacent to the stacked gate structure (for example: the stacked gate structure 116o) at the very end of the memory cell row 104. The dummy select gate 106 and the select gates 130a˜130o are fabricated using an identical material, for example. In the process of operating the memory, the dummy select gate 106 is used to open up the channel between the source region 108a and the stacked gate structure 116o only. It is not used for selecting a particular memory cell in the memory cell row 104.

The source region 108a and the drain region 108b are disposed in the substrate 100 beside the dummy select gate 108 and one side of the memory cell row 104. The source region 108a serves as a common source region and the drain region 108b serves as a bit line, for example.

The inter-layer dielectric layer 110 covers the stacked gate structures 116a˜116o, the select gates 130b˜130o, the dummy select gate 106 and the substrate 100. The plug 112 is disposed in the inter-layer dielectric layer 110 and electrically connected with the drain region 108b. The conductive layer 114 is disposed on the inter-layer dielectric layer 110 and electrically connected to the plug 112.

In the present invention, a dummy select gate is set up within the multi-level split-gate flash memory. In a programming operation, the period for programming the memory cell (for example: the stacked gate structure 116o) closest to the dummy select gate is increased to match the programming speed of the other memory cells (for example: the stacked gate structures 116a˜116o). Hence, the flash memory of the present may operate as a multi-level memory.

Because all the control gates of various stacked gate structures in a memory cell row have an identical dimension, the present invention is able to resolve the problems resulting from the non-uniformity of the memory cells. Thus, the flash memory of the present invention can operate as a multi-level memory, thereby reducing the fabrication cost.

In another embodiment, the aforementioned dummy select gate 106 can be replaced by a dummy memory cell 200. The dummy memory cell 200 is identical to other memory cells in the memory cell row. However, in an actual programming operation, the dummy memory cell will not perform any concrete operation. The dummy memory cell only serves to open up the channel between the source region 108a and the stacked gate structure 116o.

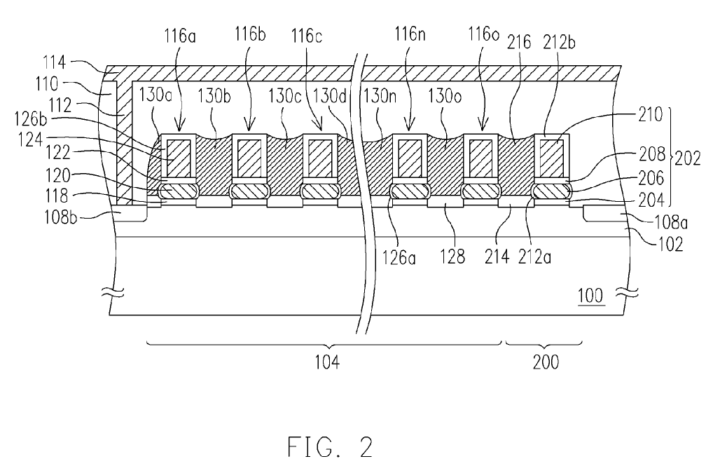

FIG. 2 is a schematic cross-sectional view of a multi-level split-gate flash memory according to another preferred embodiment of the present invention. Besides from having a dummy memory cell 200 instead of a dummy select gate 106 as shown in FIG. 1, other elements and disposition relationships shown in FIG. 2 are identical to the one in FIG. 1. Hence, a description of the elements having the same labels in FIG. 1 is omitted.

As shown in FIG. 2, the dummy memory cell 200 includes a dummy stacked gate structure 202, a dummy inter-gate dielectric layers 212a and 212b, a dummy select gate dielectric layer 214 and a dummy select gate 216.

The dummy stacked gate structure 202 of the dummy memory cell 200 is disposed on the substrate 100. The dummy stacked gate structure 202 includes a tunneling dielectric layer 204, a floating gate 206, an inter-gate dielectric layer 208 and a control gate 210 sequentially stacked over the substrate 100.

The dummy inter-gate dielectric layer 212a is disposed on the sidewall of the floating gate 206. The dummy inter-gate dielectric layer 212b is disposed on the top portion of the control gate 210 and the sidewalls of the control gate 210.

The dummy select gate dielectric layer 214 is disposed over the substrate 100 between the memory cell row 104 and the dummy stacked gate structure 202.

The dummy select gate 216 is disposed on the sidewall of the stacked gate structure 202 adjacent to the stacked gate structure 116o at the very end of the memory cell row 104. The select gate 216 covers the inter-gate dielectric layer 212a, the dummy inter-gate dielectric layer 212b and the dummy select gate dielectric layer 214. In other word, the dummy select gate 216 completely fills the gap between the stacked gate structure 116o and the dummy stacked gate structure 202.

The source region 108a and the drain region 108b are disposed in the substrate 100 beside the dummy memory cell 202 and the sidewall of the memory cell row 104.

In the present invention, a dummy memory cell is set up within the multi-level split-gate flash memory. In a programming operation, the period for programming the memory cell (for example: the stacked gate structure 116o) closest to the dummy memory cell is increased to match the programming speed of the other memory cells (for example: the stacked gate structures 116a˜116o). Hence, the flash memory of the present may operate as a multi-level memory.

Because the stacked gate structures in the entire memory cell row have an identical dimension, the present invention is able to resolve the problems resulting from the non-uniformity of the memory cells. Thus, the flash memory of the present invention can operate as a multi-level memory, thereby reducing the fabrication cost.

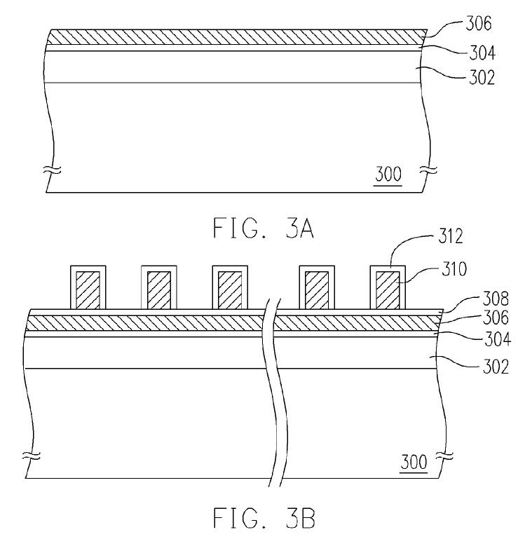

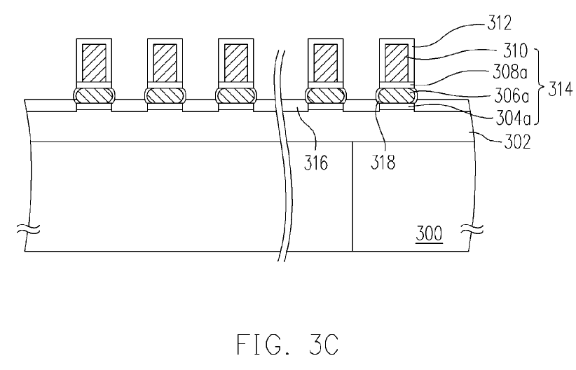

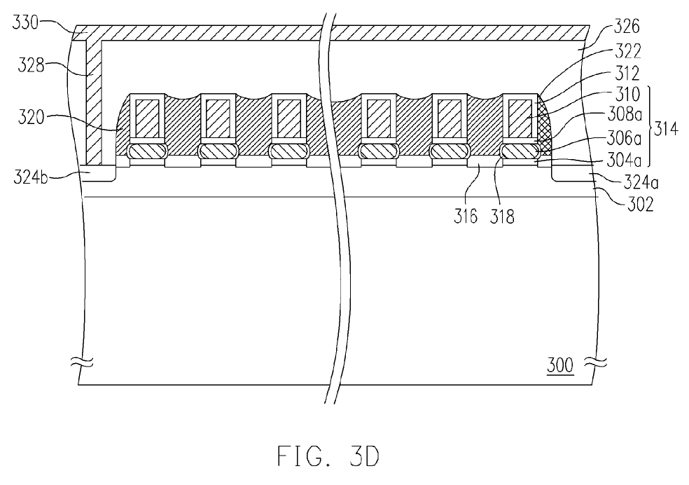

FIGS. 3A through 3D are schematic cross-sectional view showing the steps for fabricating a multi-level split-gate flash memory according to one preferred embodiment of the present invention. As shown in FIG. 3A, a substrate 300 having device isolation structures (not shown) for defining the active region thereon is provided. A P-type well 302 is formed in the substrate 300 and then a tunneling dielectric layer 304 is formed over the substrate 300. The tunneling dielectric layer 304 is a silicon oxide layer formed in a thermal oxidation, for example. Thereafter, a linear conductive layer 306 is formed over the tunneling dielectric layer 304. The conductive layer 306 is a doped polysilicon layer formed, for example, by depositing undoped polysilicon over the substrate 300 in a chemical vapor deposition process and then implanting ions into the undoped polysilicon layer.

As shown in FIG. 3B, an inter-gate dielectric layer 308 is formed over the substrate 300. The inter-gate dielectric layer 308 is an oxide/nitride/oxide composite layer. The inter-gate dielectric layer 308 is formed, for example, by performing a thermal oxidation process to form a silicon oxide layer and performing a chemical vapor deposition process to form a silicon nitride layer over the silicon oxide layer. Thereafter, wet hydrogen/oxygen gas (H₂/O₂ gas) is used to oxidize a portion of the silicon nitride layer to form another silicon oxide layer. Obviously, the inter-gate dielectric layer 308 can be a silicon oxide layer or an oxide/nitride composite layer.

A conductive layer (not shown) is formed over the substrate 300. Thereafter, the conductive layer is patterned using a mask (not shown) to form a conductive layer 310 that serves as a control gate. The conductive layer 310 is a doped polysilicon layer formed by in-situ doping in a chemical vapor deposition process, for example.

An insulating layer 312 (an inter-gate dielectric layer) is formed on the top portion and the sidewalls of the conductive layer 310. The insulating layer 312 is a silicon oxide layer formed by performing a thermal oxidation process, for example. However, the method of forming the insulating layer 312 may include depositing an insulating material layer over the substrate and then etching back the insulating material layer to retain a portion of the material over the conductive layer 310 and on the sidewalls of the conductive layer 310. Alternatively, a cap layer (not shown) is formed over the conductive layer 310 and then an insulating layer 312 is formed on the sidewalls of the conductive layer 310.

As shown in FIG. 3C, using the conductive layer 310 and the insulating layer 312 as a mask, the inter-gate dielectric layer 308, the conductive layer 306 and the tunneling dielectric layer 304 are patterned. Consequently, an inter-gate dielectric layer 308a, a conductive layer 306a and a tunneling dielectric layer 304a are formed over the substrate 300. The conductive layer 306a serves as a floating gate. In other words, the conductive layer (the control gate) 310, the inter-gate dielectric layer 308a, the conductive layer (the floating gate) 306a and the oxide layer 304a (the tunneling dielectric layer) together form a stacked gate structure 314. Thereafter, a dielectric layer 316 is formed over the exposed substrate 300 between the stacked gate structure 314 and then an insulating layer (an inter-gate dielectric layer) 318 is formed on the sidewalls of the conductive layer 306a (the floating gate). The dielectric layer 316 and the insulating layer 318 are silicon oxide layer formed, for example, by performing a thermal oxidation process.

As shown in FIG. 3D, a conductive layer 320 is formed on the sidewalls of the stacked gate structures 314. The conductive layer 320 serves as a select gate. One of the conductive layers 320 located on the sidewall at the end of the row of stacked gate structures 314 is a dummy select gate 322. The conductive layer 320 is a doped polysilicon layer formed, for example, by in-situ doping in a chemical vapor deposition process to form a conductive material layer (not shown). The conductive material layer completely fills the gap between the stacked gate structures 314. After that, a portion of the conductive material layer is removed so that only the conductive material layer between the stacked gate structures 314 and on the sidewalls of the stacked gate structures is retained. Because neighboring stacked gate structures 314 are fairly close to each other, the conductive layer 320 on the sidewalls of neighboring stacked gate structures 314 are linked together and hence the gap between the stacked gate structures 314 is completely filled.

Thereafter, using the stacked gate structures 314 and the conductive layer 320 as a mask, a source region 324a and a drain region 324b are formed in the substrate 300 beside the two conductive layers 320 (one of them is the dummy select gate 322) adjacent to the stacked gate structures at the very end of the memory cell row. The source region 324a serves as a common source region and the drain region 324b serves as a bit line, for example.

An inter-layer dielectric layer 326 is formed over the substrate 300 and then a plug 328 is formed in the inter-layer dielectric layer 326 for electrically connecting with the drain region 324b. Thereafter, a conductive layer 330 is formed over the inter-layer dielectric layer 326 for electrically connecting with the plug 328. Finally, other processes for forming a complete flash memory device is carried out. Since conventional processes are used in the remaining steps, a detailed description is omitted.

In the present invention, a dummy select gate is set up within the flash memory. In a programming operation, the period for programming the memory cell closest to the dummy select gate is increased to match the programming speed of the other memory cells.

Because the control gate inside various stacked gate structures of a memory cell row have an identical dimension, the present invention is able to resolve the problems resulting from the non-uniformity of the memory cells. Thus, the flash memory of the present invention can operate as a multi-level memory, thereby reducing the fabrication cost.

Furthermore, the method of fabricating the flash memory in the present invention is compatible to the conventional processes. The only change needed in the conventional process is to reserve a space for forming the dummy memory cell. In other words, the dummy memory cell and the memory cell row can be fabricated together. Hence, a flash memory capable of operating as a multi-level device can be fabricated without acquiring new equipment.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A multi-level split-gate flash memory, comprising:
a substrate;
a memory cell row disposed on the substrate, wherein the memory cell row comprises a plurality of serially connected memory cells, and each memory cell having:
a stacked gate structure disposed on the substrate, wherein the stacked gate structure comprises a tunneling dielectric layer, a floating gate, a first inter-gate dielectric layer and a control gate sequentially stacked over the substrate;
a select gate disposed on one sidewall of the stacked gate structure;
a second inter-gate dielectric layer disposed between the sidewall of the stacked gate structure and the select gate; and
a select gate dielectric layer disposed between the select gate and the substrate;
a dummy select gate disposed on one side of the memory cell row adjacent to the sidewall of the memory cell at the very end of the memory cell row; and
a source region and a drain region disposed in the substrate beside the dummy select gate and the memory cell row.

2. The flash memory of claim 1, wherein the control gates of the plurality of inside various memory cells have an identical width.

3. The flash memory of claim 1, wherein the dummy select gate and the select gate are fabricated using an identical material.

4. The flash memory of claim 1, wherein the source region serves as a common source region and the drain region serves as a bit line.

5. The flash memory of claim 1, wherein the first inter-gate dielectric layer comprises an oxide/nitride/oxide composite layer.

6. The flash memory of claim 1, wherein the material constituting the select gate, the floating gate, the control gate comprises doped polysilicon.

7. A multi-level split-gate flash memory, comprising:
a substrate;
a memory cell row disposed on the substrate, wherein the memory cell row comprises a plurality of memory cells, each memory cell having:
a stacked gate structure disposed on the substrate, wherein each stacked gate structure comprises a tunneling dielectric layer, a floating gate, a first inter-gate dielectric layer and a control gate sequentially stacked over the substrate;
a select gate disposed on one sidewall of the stacked gate structure;
a second inter-gate dielectric layer disposed between the sidewall of the stacked gate structure and the select gate; and
a select gate dielectric layer disposed between the select gate and the substrate;
a dummy memory cell disposed on one side of the memory cell row, wherein the dummy memory cell having:
a dummy stacked gate structure disposed on the substrate, wherein the dummy stacked gate structure comprises at least a dummy control gate; and
a dummy select gate disposed on one side of the dummy stacked gate structure wherein the dummy select gate adjacent to the sidewall of the memory cell located at the very end of the memory cell row; and
a source region and a drain region disposed in the substrate beside the dummy memory cell and the memory cell row.

8. The flash memory of claim 7, wherein the control gates of the plurality of inside various memory cells and the dummy control gate have an identical width.

9. The flash memory of claim 7, further comprises a dummy inter-gate dielectric layer disposed between the dummy select gate and the dummy stacked gate structure.

10. The flash memory of claim 7, further comprises a dummy select gate dielectric layer disposed between the dummy select gate and the substrate.

11. The flash memory of claim 7, wherein the dummy select gate and the select gate are fabricated using an identical material.

12. The flash memory of claim 7, wherein the dummy stacked gate structure and the stacked gate structure are structurally identical.

13. The flash memory of claim 7, wherein the source region serves as a common source region and the drain region serves as a bit line.

14. The flash memory of claim 7, wherein the first inter-gate dielectric layer comprises an oxide/nitride/oxide composite layer.

15. The flash memory of claim 7, wherein the material constituting the select gate, the floating gate, the control gate comprises doped polysilicon.
